(19) United States
(12) Patent Application Publication
(10) Pub. No.: US 2026/0227251 A1
(43) Pub. Date: Aug. 6, 2026

(54) DEVICE AND METHOD OF MAKING THEREOF

(71) Applicant: Nanyang Technological University, Singapore (SG)

(72) Inventors: Zhihua LIU, Singapore (SG); Shaowu PAN, Singapore (SG); Suxuan GONG, Singapore (SG); Xiaodong CHEN, Singapore (SG)

(21) Appl. No.: 19/150,620

(22) PCT Filed: Jan. 26, 2024
(86) PCT No.: PCT/SG2024/050049

§ 371 Date: Jul. 24, 2025

(30) Foreign Application Priority Data
Jan. 27, 2023 (SG) 10202300215T

(51) Int. Cl. G01L 1/22; C23C 14/20; G01B 7/16

(52) U.S. Cl. CPC G01L 1/22; C23C 14/20; G01B 7/18

(57) ABSTRACT

A device suitable for use as a stretchable sensor and a method of making thereof. The device includes a substrate, an oxidized portion of the substrate, and an electrically conductive element. The substrate is formed of an elastomer elastically stretchable along at least a first axis. The oxidized portion includes an interface interrupted by micro-cracks. The electrically conductive element is disposed on the interface. The electrically conductive element extends contiguously into and across each of a plurality of the micro-cracks, in which the plurality of the micro-cracks are anisotropically oriented. The electrically conductive element is formed with the substrate and oxidized portion being under a pre-strain. A sensor based on the device integrates a strain sensor and a pressure sensor that are configured to operate simultaneously and better mimic the “feeling of use” of human touch.

### RELATED APPLICATION

This application claims the benefit of priority to the Singapore application no. 10202300215T, filed Jan. 27, 2023, the contents of which are hereby incorporated by reference in their entirety for all purposes.

### TECHNICAL FIELD

The present disclosure relates to flexible electronics, and more particularly to a stretchable sensing device.

### BACKGROUND

Human skin is a very amazing sensory system. It enables simultaneous detection of the intensity and modes of diverse stimuli, including pressing, tapping, slipping, and bending. Real-time detection and differentiation of diverse external stimuli with one tactile sensor to mimic the human touch is very useful in many applications, including for skin-feeling related products development. While a “feeling of use” plays an important part in the consumer experience, the feeling of use is determined by the human sense. It is highly subjective and varies according to individual differences in sensory experience and in describing the experience. It is also greatly influenced by the skin condition and psychological condition. It is therefore a difficult challenge to provide an objective and quantifiable way of evaluating products in which the feeling of use is an important factor.

### SUMMARY

In one aspect, the present application describes a device including a substrate, an oxidized portion of the substrate, and an electrically conductive element. The substrate is formed of an elastomer. The substrate is elastically stretchable along at least a first axis. The oxidized portion includes an interface interrupted by micro-cracks. The electrically conductive element is disposed on the interface. The electrically conductive element extends contiguously into and across each of a plurality of the micro-cracks, in which the plurality of the micro-cracks are anisotropically oriented.

In another aspect, a system includes the device and a processor. The processor may be operably connected to the first sensing circuit and the second sensing circuit. The processor may be configured to execute computer-readable instructions stored in a memory to perform a method of determining a friction factor based on the strain force obtained from the first sensing circuit and the normal force obtained from the second sensing circuit, in which the friction factor corresponds to a tactile sense.

In another aspect, the present application discloses a method of making the device. The method includes steps of: providing oxygen plasma, stretching the oxidized portion, and forming an electrically conductive element. The method may include providing oxygen plasma to a substrate to form an oxidized portion, in which the substrate is formed of an elastomer, and in which the substrate is elastically stretchable along at least a first axis. The method may include stretching the oxidized portion along at least a first axis parallel to a lateral plane of the substrate to form a plurality of anisotropically oriented micro-cracks in an interface of the oxidized portion. The method may include, concurrently with the stretching, forming an electrically conductive element on the interface, the electrically conductive element being formed to extend contiguously into and across each of a plurality of the micro-cracks.

In yet another aspect, an evaporator is provided for forming a film on a substrate. The evaporator includes a chamber, a heater, and a rack. The chamber is operable to provide a vacuum environment. The heater may be disposed in the chamber to provide a vaporized form of a film source. The rack is disposable in the chamber. The rack includes at least a pair of clamps variably spaced apart to enable stretching of the substrate concurrently with evaporation of the film source.

### BRIEF DESCRIPTION OF THE DRAWINGS

To aid understanding, various embodiments of the present disclosure will be described with reference to the following figures:

FIG. 1A is a schematic drawing of a conventional evaporator;

FIG. 1B shows images of the results of a tape peel off test on a sample of gold-evaporated plain PDMS;

FIG. 2A and FIG. 2B are plots showing the effect of hysteresis on the sample of FIG. 1B;

FIG. 3A is a schematic diagram showing a process for making a sample of gold-evaporated oxygen plasma-treated PDMS;

FIG. 3B shows images of the results of a tape peel off test on a sample of gold-evaporated oxygen plasma-treated PDMS;

FIG. 4A to FIG. 4F are plots showing the effect of hysteresis on the sample of FIG. 3B;

FIG. 5 is a schematic drawing of an evaporator according to some embodiments of the present disclosure;

FIG. 6A is schematic flow chart illustrating a method of making a device according to some embodiments of the present disclosure;

FIG. 6B is a schematic diagram of a product of the method of FIG. 6A;

FIG. 7A is a FESEM image of a sample of gold-evaporated plain PDMS;

FIG. 7B is a chart showing the strain response of a sample of FIG. 7A;

FIG. 8A is a FESEM image of a sample of gold-evaporated oxygen plasma-treated PDMS;

FIG. 8B is a chart showing the strain response of a sample of FIG. 8A;

FIG. 9A is a FESEM image of an example of the proposed device fabricated under a 10% pre-strain;

FIG. 9B is a chart showing the strain response of the device of FIG. 9A;

FIG. 10A is a FESEM image of an example of the proposed device fabricated under a 20% pre-strain;

FIG. 10B is a chart showing the strain response of the device of FIG. 10A;

FIG. 11A is a FESEM image of an example of the proposed device fabricated under a 30% pre-strain;

FIG. 11B is a chart showing the strain response of the device of FIG. 11A;

FIG. 12 is a schematic drawing of a tactile perception sensor including the proposed device according to some embodiments of the present disclosure;

FIG. 13A to FIG. 13D are FESEM images of various components of the sensor of FIG. 12;

FIG. 14A is a partial cross-sectional side view of an example of a wearable artificial tactile perception sensor according to the present disclosure;

FIG. 14B is top view of an example of a pair of interdigital electrodes of the pressure sensor;

FIG. 15 illustrates a process of making a strain sensor part of a prototype of the wearable artificial tactile perception sensor;

FIG. 16 illustrates a process of making a pressure sensor part of the prototype;

FIG. 17A to FIG. 17C are images showing the assembling of the prototype;

FIG. 17D is an image of an assembled prototype;

FIG. 17E is an image showing the prototype of FIG. 17D worn on a finger of a user;

FIG. 18A is an image of various components of a wireless measurement module;

FIG. 18B is an image of a calibration station;

FIG. 19A to FIG. 19D are calibration curves for the prototype;

FIG. 20A and FIG. 20B are plots showing the strain response of the prototype, and FIG. 20C is a closer view of a part of FIG. 20A;

FIG. 20D shows an example of numerical fitting;

FIG. 21A to FIG. 21D show tribology results for different materials obtained using the prototype; and

FIG. 22 and FIG. 23 are images showing exemplary use scenarios of the artificial tactile perception sensor.

### DETAILED DESCRIPTION

The following detailed description is made with reference to the accompanying drawings, showing details and embodiments of the present disclosure for the purposes of illustration. Features that are described in the context of an embodiment may correspondingly be applicable to the same or similar features in the other embodiments, even if not explicitly described in these other embodiments. Additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance as generally understood in the relevant technical field, e.g., within 10% of the specified value.

As used herein, the term “and/or” includes any and all combinations of one or more of the associated listed items.

The word “exemplary” is used herein to mean “serving as an example, instance, or illustration.” Any embodiment described herein as “exemplary” is not necessarily to be construed as preferred or advantageous over other embodiments. As used herein, the singular “a” and “an” may be construed as including the plural “one or more” unless apparent from the context to be otherwise.

Terms such as “first” and “second” are used in the description and claims only for the sake of brevity and clarity, and do not necessarily imply a priority or order, unless required by the context. The terms “about” and “approximately” as applied to a stated numeric value encompasses the exact value and a reasonable variance as will be understood by one of ordinary skill in the art, and the terms “generally” and “substantially” are to be understood in a comparable manner, unless otherwise specified.

Some methods may be described in terms of steps merely to aid understanding and/or for convenient reference. The delineation between one step and another step may be merely for convenient reference in the present disclosure. It will be understood that in actual implementation there may not be a clear division or transition from one step to another subsequent step. There may be a certain amount of overlap among the steps and/or more than one step may occur or be performed concurrently in time, etc.

### Gold-Evaporated Plain PDMS

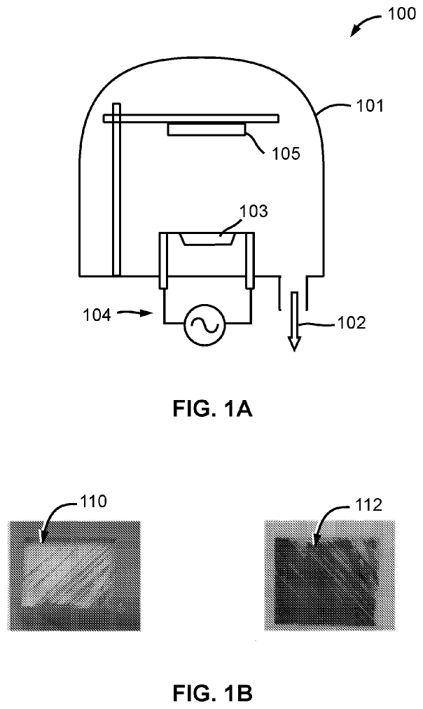

It can be demonstrated that gold (Au) that is directly coated on (intact) polydimethylsiloxane (PDMS) peels off easily. A conventional evaporator 100 such as one schematically illustrated in FIG. 1A may be used to form a thin film by thermal evaporation on a substrate. The conventional evaporator provides a chamber 101 which may be evacuated by a pump 102 to provide a vacuum environment. The coating material 103 may be controllable heated by a heater 104 to a desired temperature. The substrate 105 may be positioned to receive the evaporated coating material. In one experiment, a gold film of 75 nm (nanometers) was formed on a piece of plain PDMS. As used herein, the term “plain PDMS” refers to PDMS “as is”, e.g., PDMS that was not subject to oxygen plasma treatment. A 3M Scotch tape peel test was performed on the gold-evaporated plain PDMS. The gold-evaporated plain PDMS was also studied for its hysteresis properties.

In the tape peel test, a piece of Scotch tape (e.g., clear Scotch tape available from 3M) was first adhered to a piece of gold-evaporated plain PDMS and, subsequently, then peeled off with a force of 3 N (newtons). FIG. 1B shows images of the results of this tape peel-off test. It was observed that more than 90% of the gold film was removed by the peeled-off Scotch tape, e.g., the image on the left shows an area 110 that is the plain PDMS mostly devoid of the gold film. The image on the right shows the peeled-off Scotch tape 112 substantially covered by gold adhered to the Scotch tape and removed from the plain PDMS.

As is known, wearable electronics are typically subjected to substantial wear and tear in the course of use, necessitating robust and reliable adhesion of thin films on flexible substrates. As evident, the gold-evaporated plain PDMS is characterized by an adhesion (between the gold film and the plain PDMS) that is too low for many practical applications such as wearable electronics.

Gold-evaporated plain PDMS further exhibit significant hysteresis issues that may render them unsuitable for many applications. The hysteresis issues are attributable at least in part to the relatively weak adhesion between the gold film and the plain PDMS.

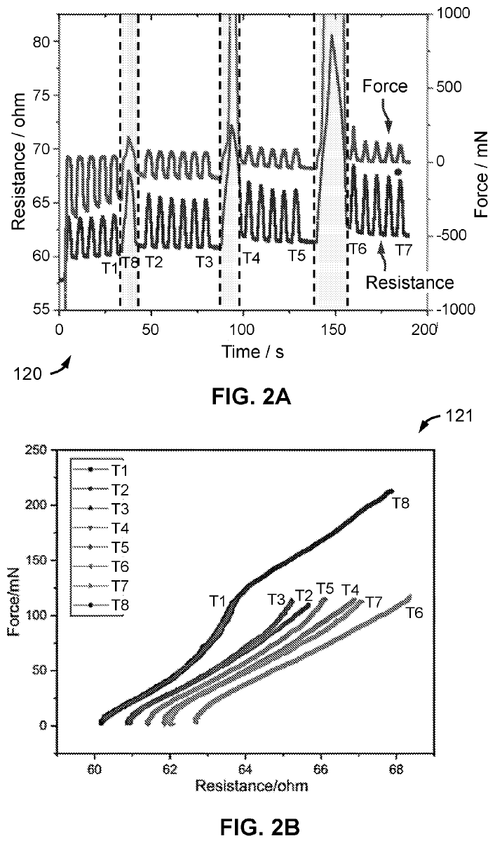

FIG. 2A and FIG. 2B show the effect of hysteresis on a strain gauge using gold-evaporated plain PDMS. FIG. 2A is a chart 120 showing the cyclic or repetitive forces applied over a period of time (with three instances of spike forces of varying magnitude) and the corresponding resistance readings of the strain gauge. There is a visible change in the resistance response especially after the instances of spike forces. FIG. 2B is a chart 121 of response curves showing the corresponding resistance-force characteristic at different time instants (T1 to T8). The hysteresis effect is evident in the shifting of the force-resistance curves and would result in inconsistent readings of the strain gauge.

Collectively, the test results suggest that gold-evaporated plain PDMS may not be a preferred choice of material for wearable electronics.

### Gold-Evaporated Oxygen Plasma-Treated PDMS

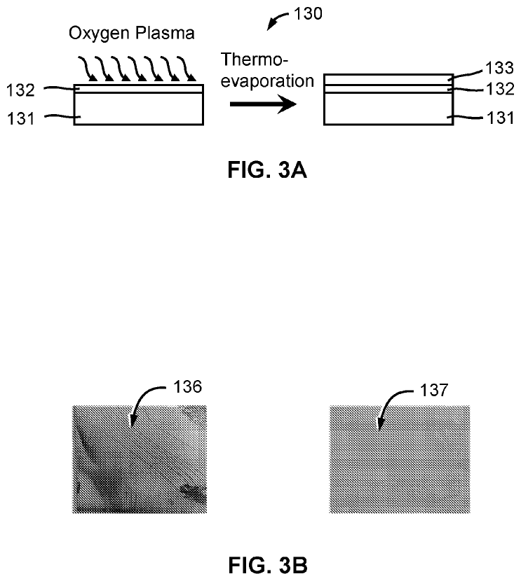

Gold films on oxygen plasma-treated PDMS can show stronger adhesion. In one experiment 130, as schematically illustrated in FIG. 3A, a piece of PDMS 131 was subjected to oxygen plasma treatment in which a layer of silicon oxide (SOₓ) 132 was formed on a surface of the PDMS. The silicon oxide layer 132 provided a comparatively more brittle or harder and more chemically reactive substrate. Gold was then to form a 75 nm film 133 of gold on the oxygen plasma-treated PDMS, e.g., by thermal evaporation 130 using a conventional evaporator 100 such as that schematically illustrated in FIG. 1A. The 3M Scotch tape peel test was performed on the gold-evaporated oxygen plasma-treated PDMS. The gold-evaporated oxygen plasma-treated PDMS was also studied for its hysteresis properties.

In the tape peel test, a piece of Scotch tape (e.g., clear Scotch tape available from 3M) was first adhered to the piece of gold-evaporated oxygen plasma-treated PDMS and, subsequently, then peeled off with a force of 3 N. FIG. 3B shows images of the results of the tape peel test. Less than 3% of the gold film was detached in the tape peel test. The image on the left shows that the oxygen plasma-treated PDMS 136 remains essentially fully covered with the gold film. The image on the right shows the peeled-off Scotch tape 137 substantially clear and without gold. The test results show that the adhesion of gold to oxygen plasma-treated PDMS was strong enough to resist being removed by the Scotch tape.

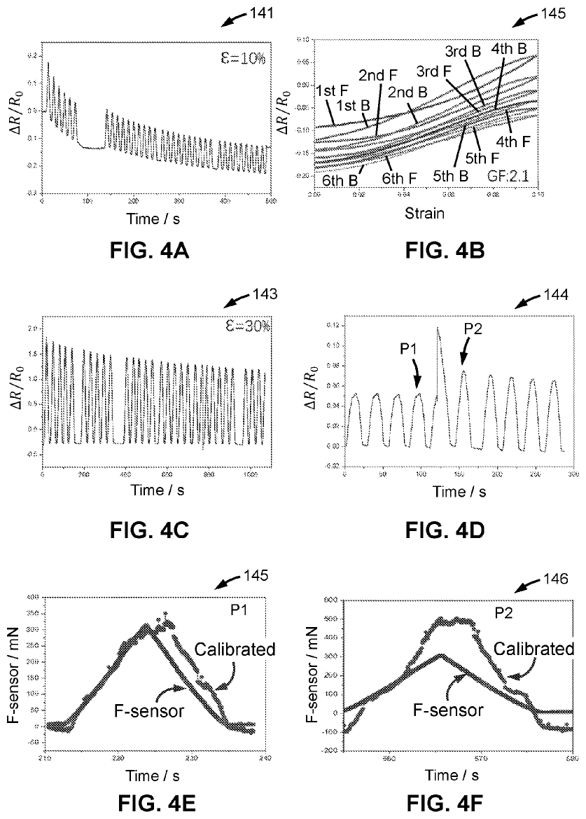

FIG. 4A is a plot 141 showing the effect of applying a cyclic 10% strain over time to a sample of gold-evaporated plain PDMS. FIG. 4B is a plot 142 showing the strain response of the same sample at different time instants. FIG. 4C is a plot 143 showing a similar hysteresis effect when a cyclic 30% strain was applied over time to a similar sample of gold-evaporated plain PDMS. As evident, the hysteresis effect results in a varying and inconsistent response.

In real-life applications, the forces experienced by a wearable electronic device or by a sensor are unlikely to remain constant throughout the useful life of the device or sensor. FIG. 4D shows is a plot 144 for a strain response to a cyclic force applied over a period of time to a strain gauge of 90 nm gold film formed on plain PDMS. An irregular instance of a larger force or strain was applied (also referred to as a “spike force” or a “spike strain”) to observe the impact of forces (or strains) of varying magnitudes. This additional strain induced an unexpected shift in the resistance curve of a sensor using the gold-evaporated oxygen plasma-treated PDMS as a strain sensing element. The shift in the resistance curve or response of the sensor eventually stabilized after several cycles.

The behaviour of the gold-evaporated oxygen plasma-treated PDMS as a sensor at P1 and P2 (respectively, before and after the spike force) is further shown in the chart 145 of FIG. 4E (P1) and in the chart 146 of FIG. 4F (P2) against a calibrated response. Using the curve generated under 10% strain as a calibration reference, FIG. 4E shows a sensor response that is similar to the calibration reference, i.e., the sensor response is acceptably accurate. However, once the sensor experiences an instance of 30% strain, the response of the sensor exhibited an error exceeding 50% of the calibrated reference. It can be seen that the response significantly changed after the spike force (or spike strain) even though similar forces (or strains) were applied before and after the spike force (spike strain).

In many real-life applications, wearable electronics (such as but not limited to stretchable sensors) may be subjected to various amounts of stretching or strain. The test results of the gold evaporated oxygen plasma-treated PDMS show that simply providing a stronger adhesion does not fully address the challenges posed in wearable electronics.

### Pre-Strained Oxidized Elastomer With Electrically Conductive Thin Film

In light of the unfavorable hysteresis effect on gold-evaporated oxygen plasma-treated PDMS, it was surprising to find that a device of the present disclosure can serve as a relatively reliable strain sensor. The device includes a substrate having a layer of elastomer with a layer of oxide (oxidized portion), e.g., formed by oxygen plasma treatment. An electrically conductive thin film was formed on the layer of oxide concurrently with a pre-strain being applied to a workpiece, in which the workpiece includes the substrate and the oxidized portion disposed on the substrate. The terms “pre-strain” and “pre-strained” may be used interchangeably for an article that was subjected to stretching forces in the course of manufacture, to differentiate from the stretching that may be experienced by the article in the course of use.

The present device of a pre-strained oxidized elastomer with electrically conductive thin film can be used in a broad range of applications, including but not limited to flexible electronics, stretchable sensors, etc. As a non-limiting example, the present device as a sensor is described below for illustrative purposes.

### Evaporator

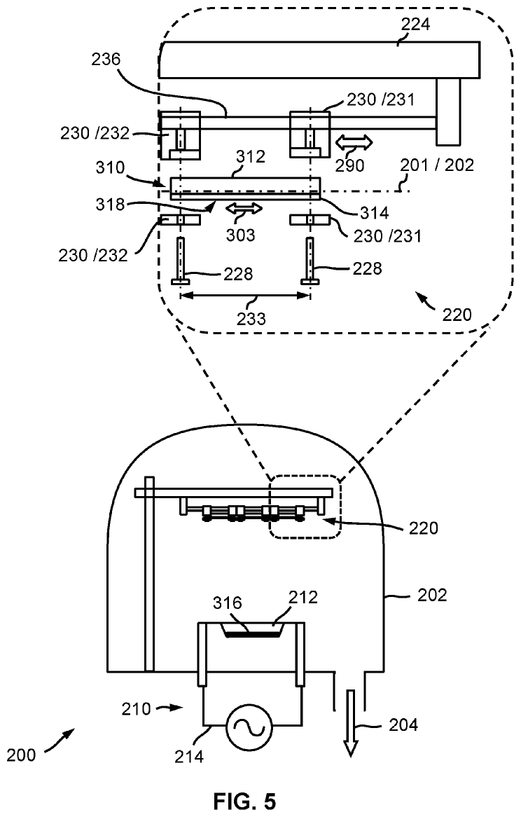

FIG. 5 is a schematic diagram of an evaporator 200 according to some embodiments of the present disclosure. The evaporator 200 is operable to form a thin film 316 on a workpiece 310. The evaporator 200 provides a chamber 202 which may be operably evacuated 204 to provide a vacuum environment, e.g., by using a vacuum pump.

The evaporator 200 includes a heater 210 disposed in the chamber 202. For example, the heater 210 may include a dish 212 for providing a film source 316 in the chamber. The film source 316 may be a precursor of the film 318 or a material of the film 318 in a non-gaseous state. The dish 212 may be connected to a heating circuit 214 such that in operation the dish 212 may be heated and in turn heat up the film source 316. The dish 212 may be controllable heated until a desired temperature is reached or until a vaporized form of the film source 316 is formed.

The evaporator 200 includes a rack 220 to serve as a workpiece holder. The rack 220 may be disposable in the chamber 202. For example, the rack 220 may be detachably mounted to a mounting 224 inside the chamber 202. The rack 220 may be detached from its mounting 224 and brought out of the chamber 202 to facilitate installation of the workpiece 310 to the rack 220.

A part of the rack 220 and the workpiece 310 is magnified to better illustrate details. The rack 220 includes at least a pair of clamps 230. In some embodiments, each pair of clamps 230 may be coupled to one or more workpieces 310. In some embodiments, each of a plurality of clamps 230 may be coupled to one workpiece 310. It will be understood that a plurality of workpieces 310 may be simultaneously processed in the chamber 202. For the sake of clarity, the following description will describe a pair of clamps 230 in connection with a workpiece 310.

In one example, the workpiece 310 is clamped at its opposing ends to respective clamps 231, 232 of a pair of clamps 230, with the clamped workpiece 310 being disposed in or parallel to a stretch plane 202. In the present disclosure, the workpiece 310 includes the substrate 312 with an oxidized portion 314. The workpiece may be disposed in the chamber 202 with a major surface of the oxidized portion 314 facing the film source 316 or exposed to the vaporized form of the film source 316.

The pair of clamps 230 are spaced apart by a clamp spacing 233 that may be varied, e.g., by adjusting the distance by which the pair of clamps 230 are spaced apart along a first axis 201. The pair of clamps 230 may be variably spaced apart to enable stretching 303 (pre-strain or pre-stretching) of the workpiece 310 concurrently with evaporation of the film source 316. In the example illustrated, one clamp 232 may be fixed relative to the mounting 224 (between the chamber 202 and the rack 220), and another clamp 231 may be slidably displaceable 290 along a bar 236 in a direction parallel to the first axis 201.

For example, the workpiece 310 may be attached to a pair of clamps 230 of the rack. The pair of clamps 230 may be spaced further apart from one another, resulting in the workpiece 310 being stretched (pre-stretching). Fasteners 228 on the rack 220 may be tightened to maintain the workpiece 310 in this pre-strained state or state of pre-strain 303. The rack 220 with the workpiece 310 may then be placed inside the vacuum chamber 202 of the evaporator 200.

In some examples, the workpiece 310 may have opposing ends coupled to respective clamps 230 (e.g., by fasteners 228 such as but not limited to threaded bolts, screws, pins, spring-loaded clips, etc.). The clamp spacing 233 is then adjusted to provide a pre-strain 303 on the workpiece 310 (e.g., by pre-stretching 303 the workpiece 310). More particularly, the pre-strain 303 is provided to the oxidized portion. 314 The clamp spacing 233 may be fixed for the duration of an evaporation process to maintain the workpiece 310 in a pre-strained state 303 throughout the evaporation process. More particularly, at least the oxidized portion 314 of the workpiece is in the pre-strained 303 state throughout the formation of the thin film.

The rack 230 enables controllable variation in the amount and/or direction of pre-strain 303 applied. The workpiece 310 may be put in a state of pre-strain 303 by displacing the pair of clamps 230 further apart. The workpiece 310 may be reverted to its default state (not under pre-strain) by moving the pair of clamps 230 closer one another, or by decoupling the workpiece 310 from the rack 220. The amount of pre-strain 303 applied to a workpiece 310 may be determined by the relative displacement 290 between the clamps 230 coupled to opposing ends of the workpiece. The pre-strain or stretching may include steps of securing the substrate to a pair of clamps 230 and increasing a clamp spacing 233 between the pair of clamps 230. The pair of clamps 230 may be spaced apart and parallel relative to one another. The pre-stretching may include increasing the clamp spacing 233 between the pair of clamps 230 by an increment spacing 290 along the first axis 201. The method was experimentally tested and found operable at least for an increment spacing 290 in a range from about 10% to about 40%, inclusive.

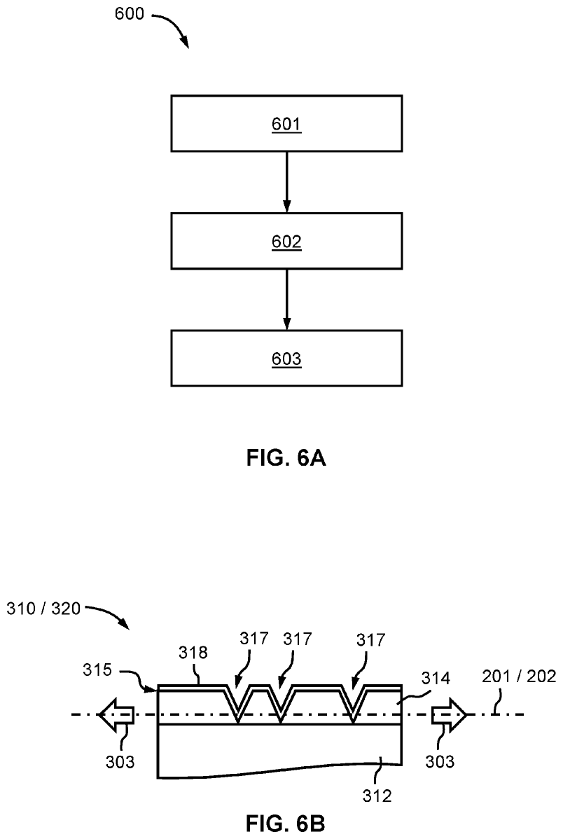

Referring to FIG. 6A and FIG. 6B, according to various embodiments of the present disclosure, a method 600 of making a device includes making a flexible electronic device 320. The device may be described as a multi-material or layered device, in which an electrically conductive film (also referred to as an electrically conductive element) 318 and a flexible layer 312 are disposed on opposing surfaces of a comparatively more brittle layer 314, with the electrically conductive element 318 extending contiguously into and across a plurality of anisotropically oriented micro-cracks 317 in the more brittle layer 314.

The method 600 may include steps of providing oxygen plasma (step 601), pre-stretching the oxidized portion (step 602), and forming an electrically conductive element (step 603).

For example, the method 600 may include providing oxygen plasma to a substrate 312 to form an oxidized portion (step 601), in which the substrate 312 is formed of an elastomer, and in which the substrate 312 is elastically stretchable along at least a first axis.

For example, the method 600 may include pre-stretching 303 the oxidized portion 314 along at least a first axis 201 parallel to a lateral plane 202 of the substrate to form a plurality of anisotropically oriented micro-cracks in an interface 315 of the oxidized portion 314. In some examples, the stretching 303 may include steps of securing the substrate 312 (or workpiece 310) to a pair of clamps 230 and increasing a clamp spacing 233 between the pair of clamps 230. The pair of clamps 230 may be spaced apart and parallel relative to one another. The stretching 303 may include increasing the clamp spacing 233 between the pair of clamps 230 by an increment spacing 290.

For example, the method 600 may include, concurrently with the stretching, forming an electrically conductive element 318 on the interface 315 between the more brittle layer and the electrically conductive element 318, the electrically conductive element 318 being formed to extend contiguously into and across each of a plurality of the micro-cracks 317.

In some examples, the method 600 includes forming an electrically conductive film 318 on the substrate 312 with the substrate 312 in the state of pre-strain, in which the substrate 312 had been treated to form a silicon oxide layer 314. The term “silicon oxide layer” is used loosely. In practice, a layer of amorphous, high-silicon-containing material, constituting a mixture of various silicon compounds, may be formed as a more brittle or oxidized portion of the substrate. In some examples, the evaporated film source 316 may form gold film (electrically conductive element) 318 on a pre-stretched 303 piece of oxygen plasma-treated PDMS 312/314. In some examples, the device 320 formed by the method 600 includes a gold-evaporated with pre-strain, oxygen plasma-treated PDMS.

FIG. 6B schematically illustrates a device 320 or product of the method 600 of FIG. 6A. The device 320 includes a stretchable substrate 312 with a more brittle portion 314, in which the more brittle portion 314 is adhered or bonded with the substrate 312 by adhesion forces sufficiently strong to withstand pre-stretching or pre-straining 303 of the substrate 312. At least the more brittle portion 314 is subject to a pre-strain 303 in a direction 201 or in a plane 202 parallel or substantially parallel to a plane in which the more brittle layer 314 is disposed. The pre-strain 303 forms or opens micro-cracks 317 in the more brittle portion 314 with the micro-cracks 317 being generally anisotropic or aligned parallel relative to one another. The micro-cracks 317 may be generally aligned transversely to the direction 201 of pre-strain.

An electrically conductive film 318 is formed on the more brittle portion 314 with the more brittle portion 314 stretched in a direction 201 or a plane 202 substantially parallel to the surface (interface 315) of the more brittle portion 314, with the micro-cracks 317 open to receive a part of the electrically conductive film 318 therein. The more brittle portion 314 may be relieved from the pre-strain 303 after forming the electrically conductive film 318. The resulting product or device 320 includes an electrically conductive film 318 (also referred to as an electrically conductive element) that extends contiguously into and across at least some of the micro-cracks 317.

### Morphology

The present device 320 may be configured as a stretchable sensor. Preferably, a stretchable sensor possesses a high sensitivity, low hysteresis, and a fast response. At the same time, the stretchable sensor needs to be soft and conformable for versatile touch feedback. The proposed device 320 was found to provide the necessary sensitivity and low hysteresis.

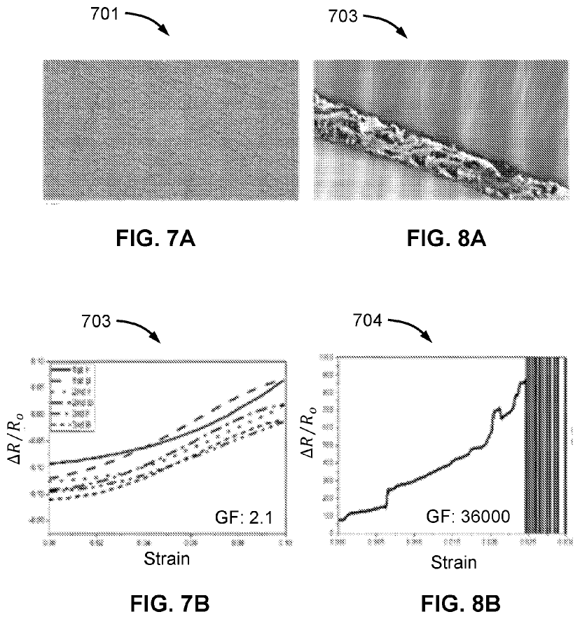

An example of the present device (gold-evaporated with pre-strain, oxygen plasma-treated PDMS) 320 was compared against gold-evaporated plain PDMS and gold-evaporated oxygen plasma-treated PDMS. The respective test samples are shown in the FESEM (field emission scanning electron microscopy) images of FIGS. 7A, 8A, 9A, 10A, and 11A. The FESEM images were captured with the respective samples at 40% strain. The electro transport response (change in forward resistance and backward resistance) under the continuous strain of 40% for the respective test samples were charted in the graphs of FIGS. 7B, 8B, 9B, 10B, and 11B.

More specifically, FIG. 7A is a FESEM (field emission scanning electron microscopy) image 701 of a sample of gold-evaporated plain PDMS. When the sample was stretched (e.g., under 4% strain), cracks in the gold film cracks could be evident. As seen in FIG. 7A, the cracks in the gold film are very small. FIG. 7B is a chart 702 of the strain response of the sample of FIG. 7A. The gage factor (GF) is very small, e.g., around 2.1. Unfortunately, the adhesion between the gold film and the plain PDMS is too low for the gold-evaporated plain PDMS to be used as a stretchable sensor, e.g., the gold film on the plain PDMS can be peeled off or detached from the plain PDMS too easily.

FIG. 8A is a FESEM image 703 of a sample of gold-evaporated oxygen plasma-treated PDMS. FIG. 8B is a chart 704 showing the strain response of the sample of FIG. 8A. The gold film of the gold-evaporated oxygen plasma-treated PDMS remains stable and will not detach or peel off, even under harsh scratching conditions. As can be seen, when the sample was stretched (e.g., under 4% strain), very large and continuous cracks appear in the gold film. The gold film was no longer electrically conductive under 2.5% strain. The gage factor of the sample was very high (about 36000). In many real-life practical applications, the sensor may suffer a strain of up to 10% or higher. Thus, gold-evaporated oxygen plasma-treated PDMS will not be considered for use as a stretchable sensor.

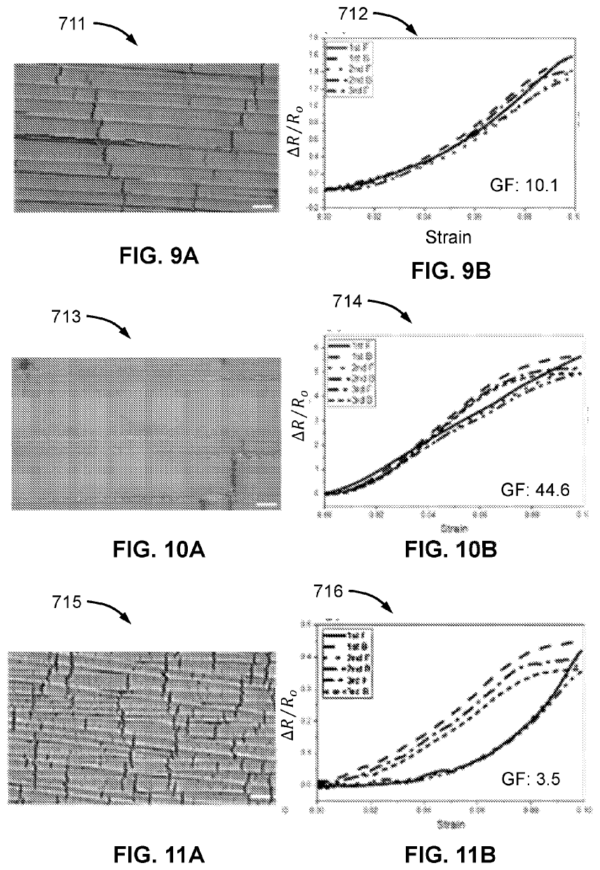

FIG. 9A is a FESEM image 711 of an example of the proposed device 320 with a pre-strain of 10%. FIG. 9B is a chart 712 showing the strain response of the device of FIG. 9A. FIG. 10A is a FESEM image 713 of an example of the proposed device 320 with a pre-strain of 20%. FIG. 10B is a chart 714 showing the strain response of the device of FIG. 10A. FIG. 11A is a FESEM image 715 of an example of the proposed device 320 with a pre-strain of 30%. FIG. 11B is a chart 716 showing the strain response of the device 320 of FIG. 11A. In these samples or examples of the proposed device 320, gold evaporation occurred with the oxygen plasma-treated PDMS under a pre-strain. It was found that new cracks were formed and the newly exposed layer at the crack domain is relatively softer compared with the non-cracked domain, giving better resistance performance than the pure hard surface of oxygen plasma-treated PDMS with no pre-strain.

The area of cracked domain increases with an increase in the pre-strain ratio (e.g., from 10% to 30%). It was observed that a higher pre-strain will give a higher hysteresis. Without being limited by theory, a higher pre-strain ratio may generate a relatively soft PDMS domain such that the adhesion force between the gold film and the soft PDMS in this area may be weak, thus showing a higher hysteresis. Various factors affect the hysteresis of a material. For example, hysteresis may be affected by the irreversible frictional energy dissipation of the polymer chains in the viscoelastic elastomers during cyclic deformation. For example, the interfacial friction and adhesion between sensory materials and electrodes, which continuously dissipates energy during repeated deformation and contact.

In the proposed device 320, it may be observed that the cracks formed in the oxidized portion of the PDMS may be at two scales, e.g., cracks dimensionally of a larger scale which are random in direction, and cracks dimensionally of a smaller scale which are generally aligned transversely to the direction of the pre-stretching.

The resistance change under strain may be improved by selecting a suitable pre-strain 303. In the experiments on chromium and gold-evaporated with pre-strain, oxygen plasma-treated PDMS, it was found that the strain and resistance ratio exhibited a substantially linear relationship or nearly linear relationship if the pre-strain was set at 20%. Such a property suggests that such a stretchable electrically conductive device 320 is suitable for use as a strain sensor.

### Wearable Artificial Tactile Perception Sensor (WATPS) Prototype

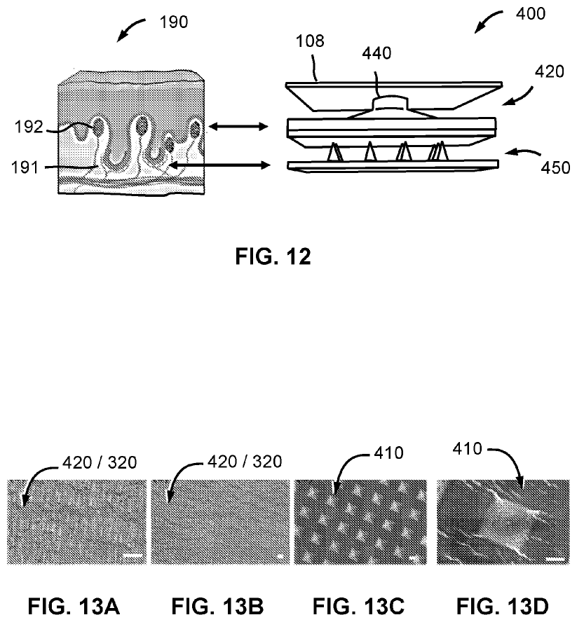

A prototype of a wearable artificial tactile perception sensor (WATPS) 400 was fabricated and tested, in which the WATPS 400 includes at least one sensing component based on the device 320. Referring to FIG. 12, the WATPS (for the sake of brevity, also referred to herein as a “sensor” or a “system”) 400 integrates a (normal) pressure sensor 450 and flexible strain sensor 420 such that, as a whole, the sensor 400 can provide feedback corresponding to a sense of a “feeling of use”. The pressure sensor 450 and the strain sensor 420 may correspond respectively to different types of sensory cells in the human skin 190, e.g., to pressure receptors 191 and friction receptors 192 in the human skin 190. For example, the WATPS 400 may include a strain sensor 420 stacked on a pressure sensor 450, with the strain sensor 450 presenting a distal tip (contact portion) for contact with an object 108.

FIG. 13A and FIG. 13B are FESEM images of the strain sensor 420 under strain, and FIG. 13C and FIG. 13D are FESEM images of a part of the pressure sensor 450. The strain sensor 420 of the WATPS 400 includes a device 320 according to embodiments of the present disclosure. For example, the strain sensor 420 of the WATPS 400 includes an electrically conductive thin film 318 formed on a comparatively brittle surface portion (e.g., oxidized layer) 314 of an elastomeric substrate 312, in which the comparatively brittle surface portion 314 is under a pre-strain 303 during the formation of the electrically conductive thin film 318 thereon. For example, the WATPS 400 includes a strain sensor 420 having a gold-evaporated with pre-strain, oxygen plasma-treated PDMS (the device 320).

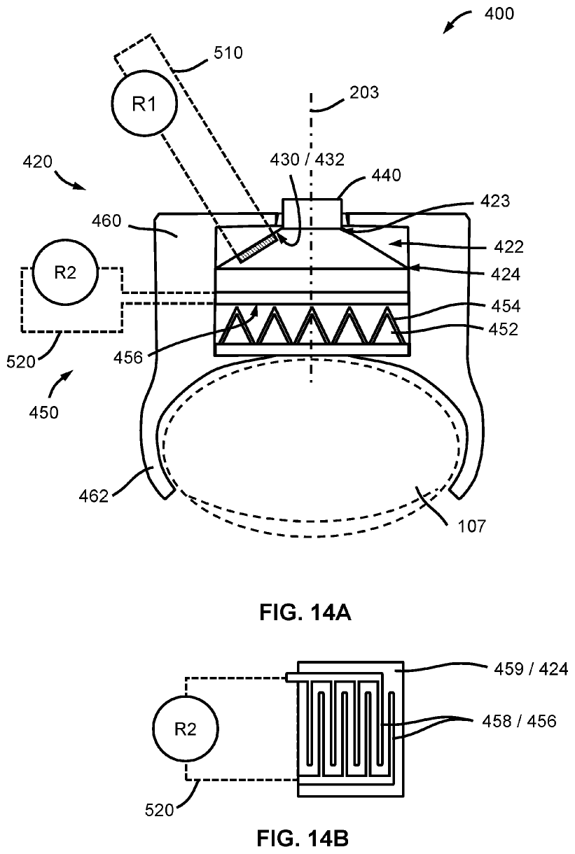

FIG. 14A is a partial cross-section view to illustrate another embodiment of a WATPS 400 of the present disclosure. The WATPS 400 includes a substrate 312, in which the substrate 312 is substantially formed of an elastomer. The substrate 312 may include a frustum-shaped portion 422 with a narrower end 423 and a wider end 424. In various examples, the frustum-shaped portion 422 may include but is not limited to a shape similar to a conical frustum, a pyramidal frustum, a polygonal frustum, or a spherical frustum.

An inner part of the frustum-shaped portion 422 may be shaped with an inclined surface 430, in which the inclined surface 430 is inclined relative to a normal axis 203. The narrower end 423 and the wider end 424 are spaced apart along the normal axis 203, e.g., spaced apart by the frustrum height (as measured along the normal axis 203).

The narrower end 423 of the substrate 312 may be referred to a distal end of the WATPS 400. The narrower end 423 of the substrate 312 may extend to a contact portion 440. The contact portion 440 may be made of the same elastomer material as the substrate 312.

A part or whole of the inclined surface 430 includes an oxidized portion 314 of the substrate 312 (or a portion that is more brittle than the elastomer 312). (Reference may be made to FIG. 6B for a schematic cross-section diagram representative of the inclined surface 430). The oxidized portion 314 and an electrically conductive element (e.g., electrically conductive thin film) 318 may be described as defining an interface 315 therebetween. That is, the oxidized portion 314 has an interface 315 interrupted by micro-cracks 317, with the electrically conductive element 318 disposed on a part or whole of the oxidized portion 314. The electrically conductive element 318 extends contiguously into and across at least some of the micro-cracks 317. In other words, the crack channels 317 are also metallized. For example, the electrically conductive element 318 may be described as extending contiguously into and across each of a plurality of the micro-cracks 317. The plurality of micro-cracks 317 are generally or substantially anisotropically oriented.

As shown schematically in FIG. 14A, the electrically conductive element 318 may be operably connected to a first sensing circuit 510. The first sensing circuit 510 may be configured to sense a strain force along a strain direction (e.g., first axis 201) inclined relative to the normal axis 203. For example, when the contact portion 440 comes into contact with an object, and when the contact portion 440 is displaced by frictional forces, the inclined surface 430 may be deformed. For example, oxidized portion 314 (on the inclined surface 430) is deformable responsive to a displacement of the inclined surface 430 relative to the wider end 424. The electrically conductive element 318 being bonded to the oxidized portion 314 will undergo corresponding deformation without breaking the first sensing circuit 510. In addition, the strain (deformation) and the resistance changes of the electrically conductive element 318 may be configured as a linear relationship (as described above) over a useful operable range. The resistance changes of the electrically conductive element 318 may be sensed by the first sensing circuit 510 and output or used in further processing.

The inclined surface 430 may optionally be shaped to define a recess 432 in the substrate to receive the electrically conductive element 318. The electrically conductive element 318 and the oxidized portion 314 may be disposed at least in the recess 432. The electrically conductive element 318 and the oxidized portion 314 may be shaped to provide electrically conductive leads from the recess to the rest of the first sensing circuit.

In FIG. 14A, the electrically conductive element 318 is illustrated as being disposed on one side of the frustum-shape portion 422 solely to avoid obfuscation. In different embodiments of the present disclosure, the electrically conductive element 318 (as well as the oxidized portion 314 over which the electrically conductive element 318 is layered) may be variously shaped and sized.

The WATPS 400 may further include a (normal direction) pressure sensor 450, e.g., to sense a normal force parallel to the normal axis 203. In some examples, the pressure sensor 450 includes an array of microstructures 452. Each of the microstructures 452 is coated with an electrically conductive coating 454. The microstructures 452 are compressible against at least one pair of electrodes 456 to close a second sensing circuit 520 with a variable resistance.

For example, the at least one pair of electrodes 456 may be a pair of interdigital electrodes 458 that are spaced apart from one another on a support 459. FIG. 14B is a top view of the pair of interdigital electrodes disposed on a support 459. When the contact portion 440 experience forces in the normal direction 203, the array of microstructures 452 are pressed by against the interdigital electrodes 459. The individual microstructures 452 are deformed and thereby changes the resistance or the potential difference in the second sensing circuit 520.

The array of microstructures 452 may be compressed in response to the normal force to provide a variable area of contact between the electrically conductive coating 454 and the pair of interdigital electrodes 456. For example, a greater force will result in a greater conductive area at the interdigital electrodes 456. For example, a smaller force may result a comparatively smaller electrically conductive area at the interdigital electrodes 456, and a corresponding comparatively larger current in the second sensing circuit 520. The support 459 for the at least one pair of interdigital electrodes 456 may be disposed at the wider end 424 of the substrate.

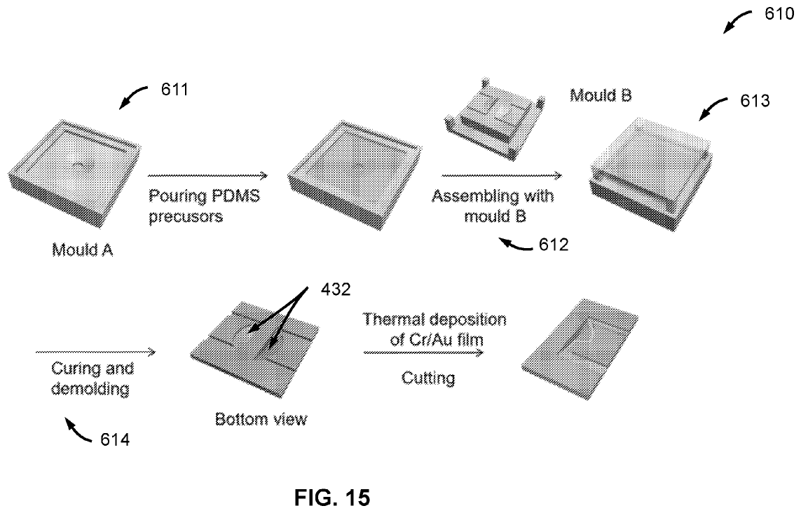

FIG. 15 shows a diagram illustrating a part of a method 610 of making the strain sensor part of the prototype. For example, a PDMS precursor may be poured into a mould (mould A) in a first moulding step 611. The moulded PDMS is assembled with a mould B in an assembly step 612 and another part of the structure is moulded thereon in a second moulding step of 613. The moulded article may be subjected to curing and demolding in a post-moulding step 614. It can be seen that the PDMS substrate is formed with at least one recess 432. An electrically conductive film (e.g., of chromium and gold) 318 may be thermally evaporated to the indented or recessed parts 432 of the substrate 312 (and more specifically to the oxidized portion 314 of the substrate 312). In this example, the sample was cut into two. The moulds may be 3D printed using VeroClear (available from Stratasys). In one example, the Cr/Au film may be 5/75 nm thick. The weight ratio of the curing agent and the base may be 1:7 in the PDMS precursor.

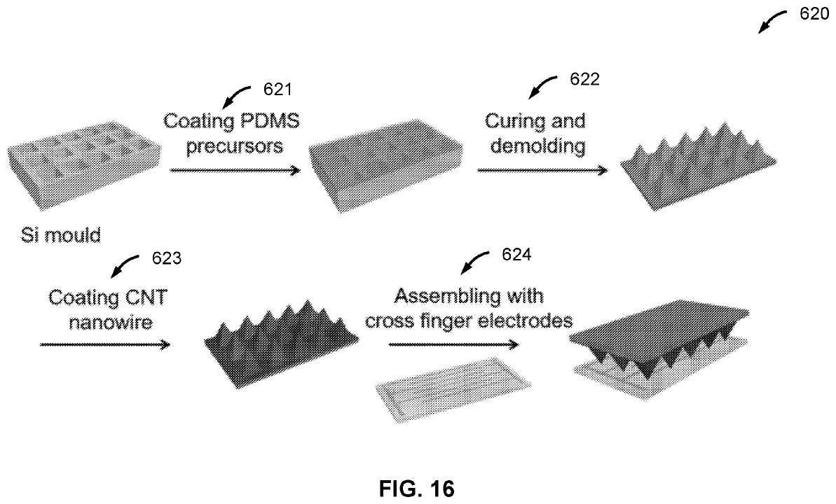

FIG. 16 shows a diagram illustrating a method 620 of making the pressure sensor part of the WATPS prototype 400. For example, a silicon mould may be coated with PDMS precursors (step 621) and moulded to form an array of microstructures (step 622). The microstructures are then coated with carbon nanotubes (CNT) or nanowires (step 623). The array of microstructures are then assembled with a pair of interdigital electrodes (step 624). The deformable microstructures in this example are pyramidal in shape, with a width of the bottom of the pyramid of 25 micrometers, but the microstructures may be variously shaped and sized in different examples.

### Materials

The various components of the WATPS 400 may be made from a variety of materials. As an illustrative example, the substrate 312 may be formed of an elastomer. The elastomer may include any one or more selected from the group consisting of a polysiloxane, a polyurethane, a rubber, and a polyvinylpyrrolidone. The elastomer may include a polydimethylsiloxane.

In some embodiments, the oxidized portion 314 may include silicon oxide. For example, a substrate of polysiloxane undergoes oxidation to form silicon oxide and a subsequently harder surface. In other examples, a substrate of polyurethane or polyvinylpyrrolidone can form a layer of higher carbon material without silicon oxide.

In some examples, the oxidized portion may be characterized by a thickness in a range from 4 microns to 6 microns, inclusive.

The electrically conductive element 318 may include any one or more selected from the group consisting of: metals, conductive organic semiconductors, conductive polymers, and conductive carbon materials. The electrically conductive element 318 may be formed of a material selected from the group consisting of: gold, platinum, copper, silver, and an alloy thereof. The electrically conductive element 318 may include any one or more selected from the group consisting of: gold, platinum, silver, copper, polyaniline, poly(3,4-ethylenedioxythiophene) polystyrene sulfonate polythiophene, carbon nanotubes, and graphene.

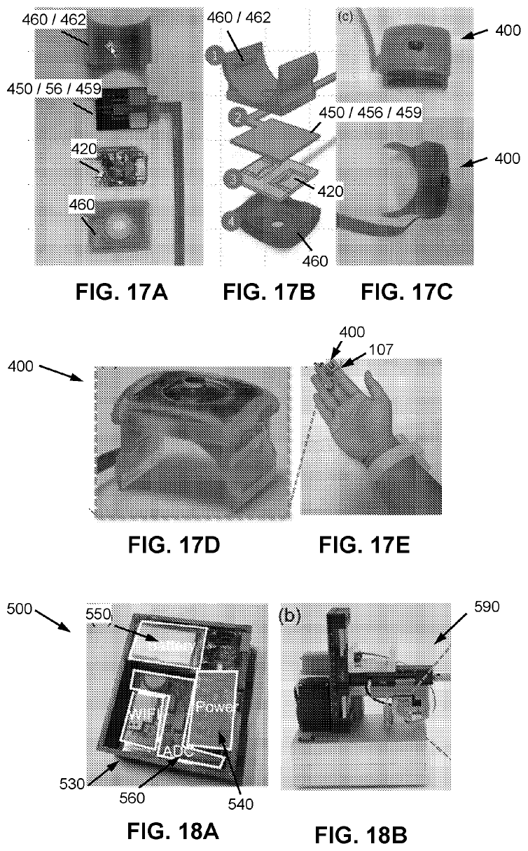

FIG. 17A to FIG. 17C show the assembly of the parts from the methods 610, 620 with the electronics such as a printed flexible cable 532. The strain sensor 420 and the pressure sensor 450 were encapsulated inside a 3D printed housing 460 (optionally including an adaptor) to waterproof the sensor 400. The contact portion 440 may protruded beyond the rest of the sensor 400 so that it may be used as a sensing tip. The housing 460 includes a wearable portion 462 (referred to as the adaptor) that was sized and shaped to snap on or grip a finger 107 firmly.

FIG. 17D and FIG. 17E are images showing the completed prototype 400 and its size on a finger 107 of a user.

The WATPS prototype 400 was made compact and portable. A wireless measurement module 500 was configured to be just slightly bigger than a watch, making it wearable on wrist. Schematically shown in FIG. 18A, the wireless measurement module 500 included a WIFI unit 530, a power management unit 540, a battery 550, and an analog-digital converter (ADC) 560, operably connected. The wireless measurement module 500 was configured to receive signals (sensed data or measurements) from the first sensing circuit 510 and the second sensing circuit 520 for further processing. In the experiments conducted, an in-situ monitoring software package (LABVIEW based) was used for data analysis and to present the data. Other software may be written to process the sensed data or measurements.

FIG. 18B is an image of a calibration station 590 developed for easy calibration of the WATPS. The calibration station 590 provides for the WATPS 400 to be mounted. The contact portion 440 of the mounted WATPS 400 can then be subjected to both frictional forces and normal forces (pressure). The calibration station 590 includes a linear motor that could be controlled to move at a precise constant speed, and thereby apply a continuously measurable force on the WATPS 400. The wireless measurement module 500 of FIG. 18A may be configured designed to control the calibration station 590.

The calibration station 590 would be useful for the initial set-up of a new sensor 400, as well as for quick on-site re-calibration to reduce any error caused by drifting. The calibration station 590 may also be used to provide some consistency between sensors from different manufacturing lines or different batches of materials.

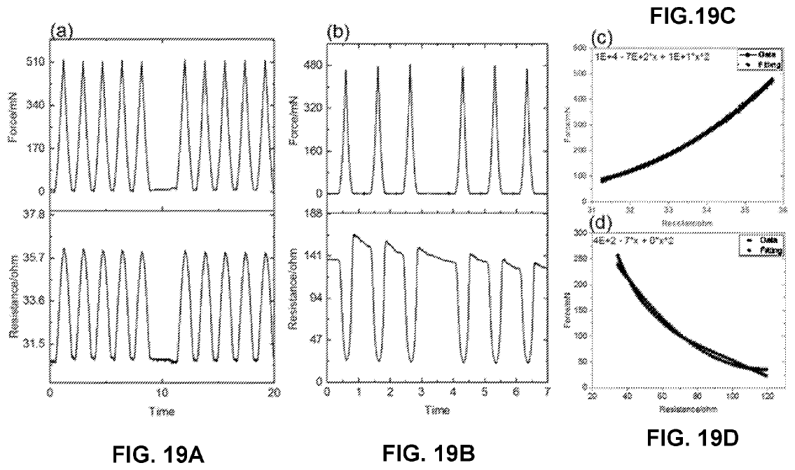

FIG. 19A to FIG. 19C show calibration curves obtained using the calibration station. FIG. 19A shows a standard curve of the strain sensor's resistance change under the applied force. By plotting the resistance change with force, the working curve of stain sensor (FIG. 19C) was obtained. Similarly, the pressure sensor may be calibrated using the calibration station. FIG. 19B shows the curve of the pressure sensors' resistance change under the applied force. The working curve of the pressure sensor (FIG. 19D) was obtained by plotting the resistance change with force.

### Performance

As elucidated previously, the incorporation of a silicon oxide layer 314 via oxygen plasma treatment on polydimethylsiloxane (PDMS) substrates 312 can contribute significantly enhanced adhesion strength between the gold film and the interface 315. A 30% pre-strain (e.g., pre-stretching) during metal evaporation process yielded remarkable reductions in hysteresis and substantial improvements in sensing capabilities.

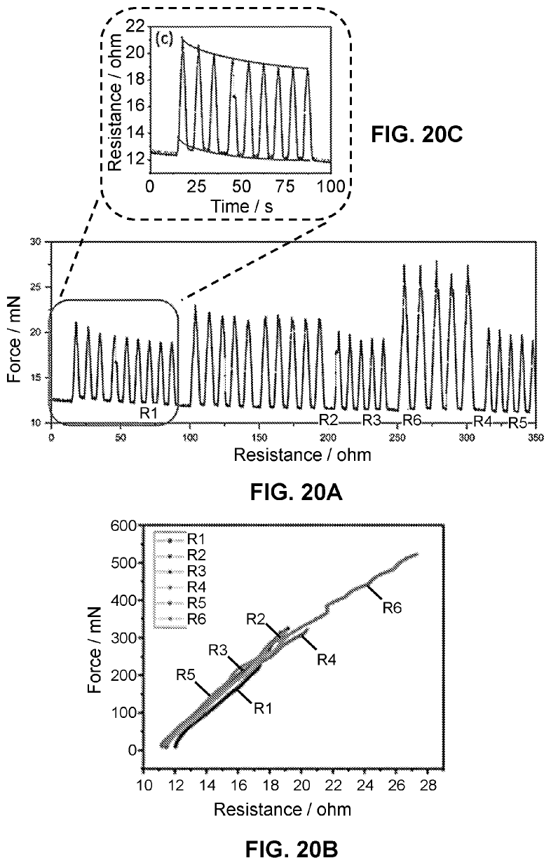

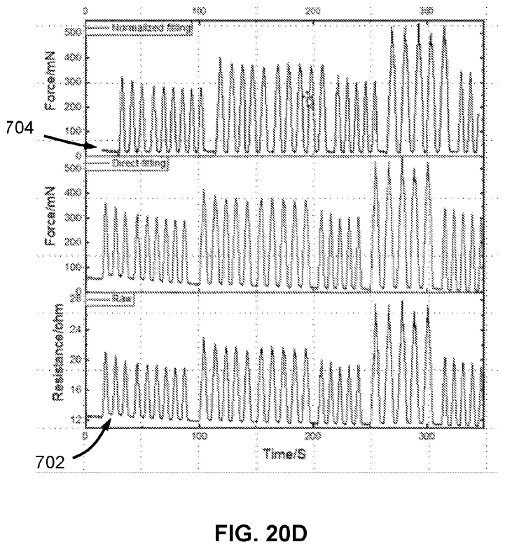

A test to mimic real-world conditions was conducted by applying varying sequences of strain to the sensor, encompassing fluctuations between 10%, 20%, and 30% strains as part of a dynamic strain application regimen. The resulting resistance-force curves, as illustrated in FIG. 20A, exhibited a consistent and distinctive behavior across diverse strain levels (FIG. 20B). This uniformity in response is a notable departure from the conventional hysteresis effects typically observed in stretchable sensors.

Upon close examination of the data in FIG. 20C, a residual drift in resistance may be observed. Nonetheless, what sets this drift apart is its consistency. The drift remains nearly identical in both stretched states and relaxed states. Such a uniform hysteresis (in which the drifting is virtually indistinguishable between the sensor's stretched and released states) lends itself well to numerical correction through signal processing/analysis algorithms. This novel approach not only circumvents the conventional hysteresis challenges but also enhances the sensor's overall stability. In other words, at least in part due to low hysteresis and the uniformity in the response of the device 320, sensors based on the device 320 can be very “light-weight” and simple as the necessary tuning (to account for the slight drift) can be done by a relatively straightforward numerical fitting. FIG. 20D further shows an example of the response curves being quickly normalized 704 to reduce or remove the slight hysteresis effect 702 seen in the raw measurement data.

Clearly, the amalgamation of oxygen plasma treatment and pre-strain processes during metallization produces a device that successfully mitigates hysteresis effects and is highly suitable for use in stretchable sensors. This substantial enhancement in sensor stability opens up a plethora of opportunities for advanced applications in wearable technology, medical devices, etc., where precise and reliable sensing is paramount.

### Sensing Various Consumer Products for “Feeling of Use”

The feel of a product that comes into contact with the human skin is important to consumer experience in many cases, e.g., cosmetics, hair care products, skin care products, etc. From the product development and manufacturer's perspective, it would be very useful to have an objective and repeatable way of gauging the “feeling of use”. The WATPS can be used to measure the smoothness of different kinds of skin-contacting products. The normal force can be sensed by pressure sensor and, simultaneously, friction force can be sensed by friction sensor. The friction factor is the friction coefficient calculated by normal force divided by strain force.

To investigate the tribology information of nonwoven fabric, two kinds of synthetic nonwoven fabrics, S1, S2, and one full cotton based nonwoven fabric, S3, were chosen. The measurement was carried out using the WATPS prototype worn on a finger of the tester. The tester performed movements typical in people touching and feeling fabric, using the hand with the finger wearing the WATPS prototype.

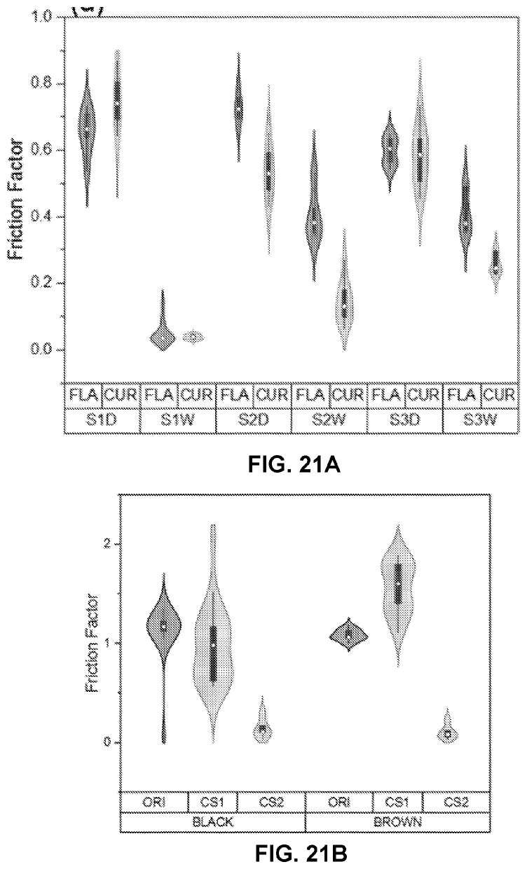

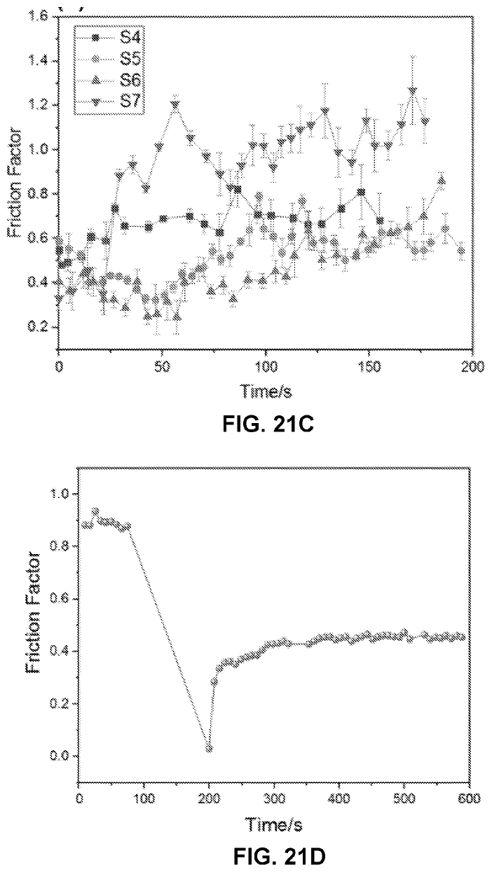

As is shown in FIG. 21A, for each type of fabric, the friction factor of the same fabric in a flat state and in a curved state gave similar readings. For example, when the fabric is dry or in a dry state, the friction factor of the fabric in both flat and curved states was about 0.6. The nonwoven used was the base materials of a commercially available cosmetic facial mask. The nonwoven fabric was allowed to fully absorb cosmetic essence compounds until the fabric was in a wet state, about as wet as a typical facial mask. The measured results of the wet fabric showed a very clear decrease in the friction factor for all nonwoven fabrics, especially for the S1 fabric which decreased to below 0.1. These results demonstrated the good stability and repeatability/consistency of the WATPS under different measurement conditions.

Hair care product affects the “feel” of the consumer's hair. The final feeling of the hair after treatment (e.g., after application of hair care products with or without rinsing off) is very important to the consumer experience and for product formula development. The WAPTS prototype could measure the frictional difference of different haircare products. For different hair samples, the results measured by the WATPS gave continuously stable readings. A slightly higher variation for high friction force sample was observed and is reasonable because the force applied on WATPS would be larger, causing bigger variations of resistance readings.

The WATPS prototype could distinguish the smoothness of hair. As is shown at FIG. 21B, in the original state, both the black hair sample and the brown hair sample gave a similar friction factor at 1.1. After water treatment of a shampoo, CS1, the hair samples showed similar friction factors but a higher data variation. This is because contamination at the hair surface had been removed, giving higher friction force readings. After the hair was treated by a conditioner product, CS2, the friction factor dramatically decreased to 0.1. The measured result (using the WATPS) showed a high degree of consistency with the feel on the fingers (unaided human perception).

The WATPS prototype was further used in experiments to sense the surface of human skin treated with different cosmetics products. As shown in FIG. 21C, the friction factor increased with time after applying the cosmetic products. It was observed that the absorption behaviour is different for different cosmetic products. The absorption of the essence product S4 and the moisturizer S7 ended at around 25 seconds, and each gave a relatively consistent final feel for the rest of the time tested. Cream products S5 and S6 exhibited a slower absorption and a corresponding relatively smoother final skin feeling.

The WATPS could measure the absorption process in an artificial polymer fabric with the help of a robotic actuator (to provide measurable and repeatable movement in performing the tests). Before applying cosmetic essence product S4, the friction factor of polymer fabric was around 0.9. After applying the cosmetic essence product S4, the surface friction factor initially decreased to almost 0, indicating a very smooth layer of product on the polymer fabric. After a period of time, the friction force increased to around 0.4 (FIG. 21D). This was because a part of the compounds inside the S4 product had been absorbed by the polymer fabric, leaving a relatively less smooth layer of compounds at the surface. The WATPS can therefore be used to test for partial absorption of a component of the cosmetic product by the skin.

### Various Industrial Applications

Advantageously, the present device enables a friction sensor and a pressure sensor to be small enough to be integrated and still fit on a finger-tip. This enables the integrated sensor to integrate simultaneous friction sensing and pressure sensing, and thereby better mimic the “feeling of use” of human touch. Alternatively described, responsive to one physical contact, the proposed sensor simultaneously provides a first signal corresponding to a pressure receptor sensing and a second signal corresponding to a friction receptor sensing.

The integrated sensor simultaneously provides sensory feedback in more than one way in the course of performing one physical contact (between a part of the sensor and an object) and, in this manner, is more similar to actual human touch. The proposed sensor can be used for the sensing of surface tribology information in an in-situ or ex-situ way. It may be used to approximate in a quantifiable manner the customer's likely perception of a product, e.g., in terms how the product feels to the customer's skin/fingers, and how the skin feels after applying the product. The sensor can be useful for acquiring hair tactile impressions of different hair treatment products, such as shampoos, conditioners, and colorant compounds, etc. The sensor can also be useful for sensing any surface related qualities such as surface smoothness to human touch.

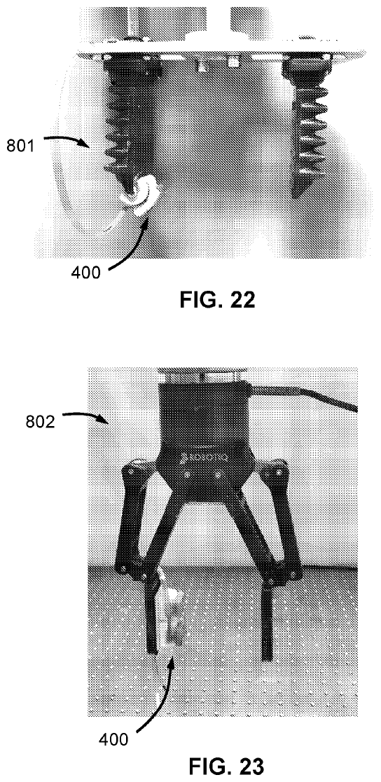

The integrated sensor can be applied to a broad range of applications including, and not limited to, providing robots with a more complex sense of touch for more delicate or accurate handling and manipulation tasks. Solely for illustrative purposes and not to be limiting, a few examples are shown in FIG. 22 and FIG. 23. FIG. 22 is an image of a prototype of the integrated sensor 400 mounted to a robotic finger 801. FIG. 23 is an image of a prototype of the integrated sensor 400 mounted to another type of robotic grippers 802.

The proposed device has many useful applications, including but not limited to application in a wearable sensor, a fingertip-sized sensor capable of mimicking human tactile perception, etc. Examples of the device as a sensor have been described above to aid understanding, and it will be understood that the examples are merely illustrative, and the following description does not limit the use of the proposed device to sensing alone.

Alternatively described, a WATPS system is developed for tactile perception understanding. Four parts are integrated into the WATPS system, including: a friction sensor, a pressure sensor, a calibration station, and an in-situ wireless sensing data transport and analysis software package. The sensor is capable of sensing both friction and normal force at same time to provide information of friction factors.

One of features of interest of the present method is to apply a pre-strain after plasma treatment. The pre-strain makes the resulting devices stable and further provides a way to tune or pre-design the sensor performance. A conductive material (e.g., gold) was used in the prototype but other materials such as Pt, Cu, Ag, etc., may also be used. As described above, the gold that is directly coated on PDMS can be peeled off very easily, but the gold on plasma treated PDMS cannot be peeled off at all. Compared to the conventional, the present device demonstrated good stability, which provides the foundation for performance, repeatability, and long useful life. Experimental results showed that the device proposed herein outperforms a conventional metal-coated elastomer in terms of stability, repeatability, and useful life.

In the experiments, a simple circuit suffices to provide accurate measurements. For example, a good signal-to-noise ratio (SNR) of more than 50 could be obtained using just one analog-to-digital converter (ADC) and one serially connector resistor. The experiments demonstrated that the gauge factor of the present device provided significant improvement over the conventional metal-coated elastomer such that a complex signal processing circuit was not necessary. This means that the measurement circuit can be relatively small and easier to miniaturize. For example, since a complex signal processing circuit is not required, the present device enables a measurement device that is smaller than the size of a watch.

Hysteresis is a big issue in stretchable sensors. As described above, a conventional gold directly coated PDMS shows very clear hysteresis at different level of strains. A huge hysteresis or non-predicable device resistance will occur when a relatively larger strain is applied. This larger strain causes the sensor response to change. That is, the sensor gave a totally different resistance response before and after the relatively larger strain. The change can be as a new response that is 60% higher at the same strain level.

The proposed device exhibited a greatly reduced hysteresis, demonstrating a significant improvement over the conventional metal-coated elastomer in terms of a significantly reduced hysteresis. By applying a pre-strain after plasma treatment, the resulting device as proposed herein can control the hysteresis very well, giving a stable resistance response at different strain level, regardless of any significant larger strains that may be experienced. It was experimentally verified that the sensor gave the same performance under different strains with no drifting issues.

The WATPS prototype fabricated was successfully used for skincare, hair, and nonwoven texture product related consumer studies. It not only showed good agreement with the human perception, but also quantitated a detailed understanding of the improvement to the surface status improvement for different products. The prototype worked well not only on dry samples, but also on wet samples. The prototype could work well even for underwater usage (using a prototype in which the sensors were encased and sealed in a waterproof housing/adaptor).

In one aspect, the WATPS was inspired by the human skin perception system in that different receptors are involved, e.g., the Meissners Corpuscle senses friction forces, and the Merkel cell located at a relative deeper position in skin senses pressure. The WATPS system combines two types of stretching sensors packed along a reference direction (also referred to herein as the normal direction).

The friction sensor is located nearer the contact with the object, and is fabricated by coating nanometer-thick gold layer onto pre-strained oxygen plasma-treated PDMS by thermal evaporation (with the oxygen plasma used to generate a hard silicon oxide film). Once the sensor senses a frictional force, it will deform under the force direction. Micro-cracks on the electrically conductive film will be induced under the strain. By measuring the change of resistance, a friction force loading on the sensor could be ascertained.

The pressure (normal force) sensor is located spaced apart from the contact portion by the friction sensor. The pressure sensor may be fabricated with conductive material coated micro-pyramid-structured PDMS disposed on cross-finger electrode. The electrical conductance is proportional with applied force in the normal direction. Silver nanowire, evaporated gold, and carbon nanotube (CNT) with variable thickness by different fabrication methods may be used to form the conductive layer. Preferably, the pressure sensor uses spray coated CNT as the electrically conductive coating, as it demonstrated a good performance in terms of the conductivity changing range and hysteresis.

The foregoing has provided a detailed description of various aspects of the present disclosure. In one aspect, the proposed device includes a substrate, an oxidized portion of the substrate, and an electrically conductive element. The substrate is formed of an elastomer. The substrate is elastically stretchable along at least a first axis. The oxidized portion includes an interface interrupted by micro-cracks. The electrically conductive element is disposed on the interface. The electrically conductive element extends contiguously into and across each of a plurality of the micro-cracks, in which the plurality of the micro-cracks are anisotropically oriented.

The electrically conductive element may be bonded to the substrate by the oxidized portion. The interface further includes a network of continuous cracks.

The micro-cracks are characterized by a micro-crack length. The continuous cracks are characterized by a crack length at least one order of magnitude longer than the micro-crack length.

The device in which the micro-cracks are formed with the oxidized portion in a pre-strained state.

The micro-cracks may be formed by applying stretching forces along the first axis to a workpiece, in which the workpiece includes the substrate and the oxidized portion disposed on the substrate.

The micro-cracks may be aligned to extend transversely to the first axis.

The substrate may include: a narrower end, a wider end, and an inclined surface extending between the narrower end and the wider end. The wider end may be spaced apart from the narrower end along a normal axis. The inclined surface may be inclined relative to the normal axis. The oxidized portion may be disposed on the inclined surface. The oxidized portion may be deformable responsive to a displacement of the inclined surface relative to the wider end.

The inclined surface may define a recess in the substrate. The electrically conductive element and the oxidized portion may be disposed in the recess.

The substrate may include a frustum-shaped portion between the narrower end and the wider end. The inclined surface may form an inner part of the frustum-shaped portion.

The frustum-shaped portion may be configured with any one profile selected from the group consisting of: a conical frustum, a pyramidal frustum, a polygonal frustum, and a spherical frustum.

The electrically conductive element may be operably connected to a first sensing circuit. The first sensing circuit may be configured to sense a strain force along a strain direction orthogonal to the normal axis.

The device may further include a pair of interdigital electrodes disposed across the wider end. The interdigital electrodes may be operably connected to a second sensing circuit. The second sensing circuit may be configured to sense a normal force along a normal direction parallel to the normal axis.

The device may further include an array of microstructures having an electrically conductive coating. The array of microstructures may be compressible in response to the normal force to provide a variable area of contact between the electrically conductive coating and the pair of interdigital electrodes.

The substrate, the pair of interdigital electrodes, and the array of microstructures may be aligned along the normal axis. The pair of interdigital electrodes may be disposed between the substrate and the array of microstructures.

The elastomer may include any one or more selected from the group consisting of a polysiloxane, a polyurethane, a rubber, and a polyvinylpyrrolidone.

The elastomer may include a polydimethylsiloxane.

The oxidized portion may include silicon oxide.

The oxidized portion may have a thickness in a range from 4 microns to 6 microns, inclusive.

The electrically conductive element may include any one or more selected from the group consisting of: metals, conductive organic semiconductors, conductive polymers, and conductive carbon materials.

The electrically conductive element may include any one or more selected from the group consisting of: gold, platinum, silver, copper, polyaniline, poly(3,4-ethylenedioxythiophene) polystyrene sulfonate polythiophene, carbon nanotubes, and graphene.

In another aspect, the present disclosure describes a system. The system includes the device and a processor. The processor may be operably connected to the first sensing circuit and the second sensing circuit. The processor may be configured to execute computer-readable instructions stored in a memory to perform a method of determining a friction factor based on the strain force obtained from the first sensing circuit and the normal force obtained from the second sensing circuit, in which the friction factor corresponds to a tactile sense.

The processor may be configured to calibrate the friction factor against a predetermined reference.

The system may further include a wearable housing. The wearable housing may be coupled to the substrate at least at the wider end, in which the narrower end extends to a contact portion facing out of the wearable housing.

In another aspect, the present disclosure describes a method of making the device. The method includes steps of: providing oxygen plasma, stretching the oxidized portion, and forming an electrically conductive element. The method may include providing oxygen plasma to a substrate to form an oxidized portion, in which the substrate is formed of an elastomer, and in which the substrate is elastically stretchable along at least a first axis. The method may include stretching the oxidized portion along at least a first axis parallel to a lateral plane of the substrate to form a plurality of anisotropically oriented micro-cracks in an interface of the oxidized portion. The method may include, concurrently with the stretching, forming an electrically conductive element on the interface, the electrically conductive element being formed to extend contiguously into and across each of a plurality of the micro-cracks.

The stretching may include steps of securing the substrate to a pair of clamps and increasing a clamp spacing between the pair of clamps. The pair of clamps may be spaced apart and parallel relative to one another. The stretching may include increasing the clamp spacing between the pair of clamps by an increment spacing in a range from 10% to 40%, inclusive, wherein the increment spacing is along the first axis.

In the method, the substrate may be formed of an elastomer. The elastomer may include any one or more selected from the group consisting of a polysiloxane, a polyurethane, a rubber, and a polyvinylpyrrolidone, in which a strain applied during the stretching is in a range of 10% to 40% strain, inclusive.

The oxidized portion may include an oxide of silicon.

The oxidized portion may be characterized by a thickness in a range from 4 microns to 6 microns, inclusive.

The electrically conductive element may be formed of a material selected from the group consisting of: gold, platinum, copper, silver, and an alloy thereof.

The method in forming the electrically conductive element includes thermal evaporation.

In yet another aspect, an evaporator is provided for forming a film on a substrate. The evaporator includes a chamber, a heater, and a rack. The chamber is operable to provide a vacuum environment. The heater may be disposed in the chamber to provide a vaporized form of a film source. The rack is disposable in the chamber. The rack includes at least a pair of clamps variably spaced apart to enable stretching of the substrate concurrently with evaporation of the film source.

All examples described herein, whether of apparatus, methods, materials, or products, are presented for the purpose of illustration and to aid understanding, and are not intended to be limiting or exhaustive. Modifications may be made by one of ordinary skill in the art without departing from the scope of the claimed invention.

1. A device comprising:
a substrate, the substrate being formed of an elastomer, the substrate being elastically stretchable along at least a first axis;
an oxidized portion of the substrate, the oxidized portion having an interface interrupted by micro-cracks; and
an electrically conductive element disposed on the interface,
wherein the electrically conductive element extends contiguously into and across each of a plurality of the micro-cracks, the plurality of the micro-cracks being anisotropically oriented.

2. The device as recited in claim 1, wherein the electrically conductive element is bonded to the substrate by the oxidized portion.

3. The device as recited in claim wherein the interface further comprises a network of continuous cracks.

4. The device as recited in claim 3, wherein the micro-cracks are characterized by a micro-crack length, and wherein the continuous cracks are characterized by a crack length at least one order of magnitude longer than the micro-crack length, wherein the micro-cracks are formed with the oxidized portion in a pre-strained state.

5. (canceled)

6. The device as recited in claim 1, wherein the micro-cracks are formed by applying stretching forces along the first axis to a workpiece, the workpiece comprising the substrate and the oxidized portion disposed on the substrate, wherein the micro-cracks are aligned to extend transversely to the first axis.

7. (canceled)

8. The device as recited in claim 1, wherein the substrate comprises:
a narrower end;
a wider end, the wider end being spaced apart from the narrower end along a normal axis; and
an inclined surface extending between the narrower end and the wider end, the inclined surface being inclined relative to the normal axis, and
wherein the oxidized portion is disposed on the inclined surface, the oxidized portion being deformable responsive to a displacement of the inclined surface relative to the wider end.

9. The device as recited in claim 8, wherein the inclined surface defines a recess in the substrate, and wherein the electrically conductive element and the oxidized portion are disposed in the recess.

10. The device as recited in claim 6, wherein the substrate comprises a frustum-shaped portion between the narrower end and the wider end, and wherein the inclined surface forms an inner part of the frustum-shaped portion.

11. (canceled)

12. The device as recited in any one of claim 8, wherein the electrically conductive element is operably connected to a first sensing circuit, the first sensing circuit being configured to sense a strain force along a strain direction orthogonal to the normal axis.

13. The device as recited in claim 12, further comprising a pair of interdigital electrodes disposed across the wider end, the interdigital electrodes being operably connected to a second sensing circuit, the second sensing circuit being configured to sense a normal force along a normal direction parallel to the normal axis.

14. The device as recited in claim 13, further comprising an array of microstructures having an electrically conductive coating, wherein the array of microstructures is compressible in response to the normal force to provide a variable area of contact between the electrically conductive coating and the pair of interdigital electrodes.

15. The device as recited in claim 14, wherein the substrate, the pair of interdigital electrodes, and the array of microstructures, are aligned along the normal axis, and wherein the pair of interdigital electrodes are disposed between the substrate and the array of microstructures.

16. (canceled)

17. (canceled)

18. (canceled)

19. The device as recited in any one of claim 1, wherein the oxidized portion has a thickness in a range from 4 microns to 6 microns, inclusive.

20. (canceled)

21. (canceled)

22. A system comprising:
the device as recited in claim 12; and
a processor operably connected to the first sensing circuit, and the second sensing circuit, the processor being configured to execute computer-readable instructions stored in a memory to perform a method of determining a friction factor based on the strain force obtained from the first sensing circuit and the normal force obtained from the second sensing circuit,
wherein the friction factor corresponds to a tactile sense.

23. The system as recited in claim 22, wherein the processor is configured to calibrate the friction factor against a predetermined reference.

24. The system as recited in claim 22, further comprising:
a wearable housing, the wearable housing being coupled to the substrate at least at the wider end, and
wherein the narrower end extends to a contact portion facing out of the wearable housing.

25. A method of making a the device, comprising:
providing oxygen plasma to a substrate to form an oxidized portion, the substrate being formed of an elastomer, the substrate being elastically stretchable along at least a first axis;
stretching the oxidized portion along at least a first axis parallel to a lateral plane of the substrate to form a plurality of anisotropically oriented micro-cracks in an interface of the oxidized portion; and
concurrently with the stretching, forming an electrically conductive element on the interface, the electrically conductive element being formed to extend contiguously into and across each of a plurality of the micro-cracks, wherein the stretching comprises:
securing the substrate to a pair of clamps, the pair of clamps being spaced apart and parallel relative to one another; and
increasing a clamp spacing between the pair of clamps by an increment spacing in a range from 10% to 40%, inclusive, wherein the increment spacing is along the first axis.

26. (canceled)

27. The method as recited in claim 25, wherein the substrate is formed of an elastomer, the elastomer comprising any one or more selected from the group consisting of a polysiloxane, a polyurethane, a rubber, and a polyvinylpyrrolidone, and wherein a pre-strain applied during the stretching is in a range of 10% to 40% strain, inclusive.

28. The method as recited in claim 27, wherein the oxidized portion comprises an oxide of silicon, and wherein the electrically conductive element is formed of a material selected from the group consisting of gold, platinum, copper, silver, and an alloy thereof.

29. (canceled)

30. (canceled)

31. The method as recited in any one of claim 25, wherein the step of forming the electrically conductive element comprises thermal evaporation.

32. (canceled)
